(19) United States
(12) Patent Application Publication
(10) Pub. No.: US 2016/0021445 A1
(43) Pub. Date: Jan. 21, 2016

(54) MODULAR AUDIO SYSTEM

(71) Applicant: RedSonic Sound, Inc., Stamford, CT (US)

(72) Inventor: Jonathan REDMOND, Stamford, CT (US)

(73) Assignee: REDSONIC SOUND, INC., Stamford, CT (US)

(21) Appl. No.: 14/799,847

(22) Filed: Jul. 15, 2015

Related U.S. Application Data
(60) Provisional application No. 62/025,235, filed on Jul. 16, 2014.

(51) Int. Cl. H04R 1/02; H01R 33/92; H03F 3/181

(52) U.S. Cl. CPC H04R 1/02; H03F 3/181; H01R 33/92; H04R 2420/09

(57) ABSTRACT

A modular audio system is described. The modular audio system may include a support unit having a base portion, a plurality of connector supports, each of the plurality of connector supports being coupled to the base portion, and a plurality of connectors, each of the plurality of connectors being coupled to a respective connector support, the plurality of connectors being adapted to physically join an external device to the support unit. The modular audio system may also include a modular speaker unit having a digital signal processing unit that is disposed within the modular speaker unit and adapted to receive an input signal and a control signal, and an amplifier that is disposed within the modular speaker unit and adapted to drive a speaker diaphragm.

### CROSS REFERENCE TO RELATED APPLICATION

The present application claims priority to U.S. Provisional Application Ser. No. 62/025,235 filed Jul. 16, 2014, the disclosure of which is incorporated herein by reference in its entirety.

### FIELD OF INVENTION

The present invention relates to electronic sound systems and, more particularly, to a modular audio system.

### DISCUSSION OF RELATED ART

A variety of audio systems are currently available. Despite its large size and heavy weight, the “Marshall Stack” continues to remain the configuration of choice in the music industry. A typical Marshall Stack includes an amplifier stacked on top of at least two large speaker cabinets.

Recently, advances towards lightweight modular speakers have been made. For example, U.S. patent application Ser. No. 14/211,044, entitled “Modular Speaker System,” filed on Mar. 14, 2014, discloses a modular speaker system and is hereby incorporated by reference in its entirety. In the modular speaker system, a speaker unit includes a connector adapted to form a physical connection with a cooperating connector of a second speaker unit in order to physically join the speaker unit to the second speaker unit. The speaker unit may also include an electrical coupling that is automatically engaged with an electrical coupling of a second speaker unit when the connectors are fully engaged.

While the modular speaker system provides significant advantages as compared to conventional speaker systems, additional improvements may be implemented to achieve a modular audio system.

### SUMMARY OF THE INVENTION

The present invention is directed to a modular audio system that substantially addresses one or more limitations or disadvantages of the related art. Features and advantages of the invention are set forth in the description which follows, or will be apparent from the description, or may be learned by practice of the invention.

In one example, a modular audio system includes a support unit having a base portion, a plurality of connector supports, each of the plurality of connector supports being coupled to the base portion, and a plurality of connectors, each of the plurality of connectors being coupled to a respective connector support, the plurality of connectors being adapted to physically join an external device to the support unit.

In another example, a modular audio system includes a modular speaker unit having a digital signal processing unit that is disposed within the modular speaker unit and adapted to receive an input signal and a control signal, and an amplifier that is disposed within the modular speaker unit and adapted to drive a speaker diaphragm.

It is to be understood that both the foregoing general description and the following detailed description are exemplary and explanatory and are not intended to limit the invention to the described examples.

### BRIEF DESCRIPTION OF THE DRAWINGS

FIG. 1 illustrates a support unit arranged in an example configuration.

FIGS. 2A and 2B illustrate a support unit coupled to modular speakers in an example configuration.

FIGS. 3A-3D illustrate an audio system arranged in an example configuration.

FIG. 4 illustrates a circuit block diagram of a modular speaker unit in an example configuration.

FIG. 5 illustrates an audio system arranged according to another example configuration.

FIG. 6 illustrates an audio system arranged according to another example configuration.

### DETAILED DESCRIPTION

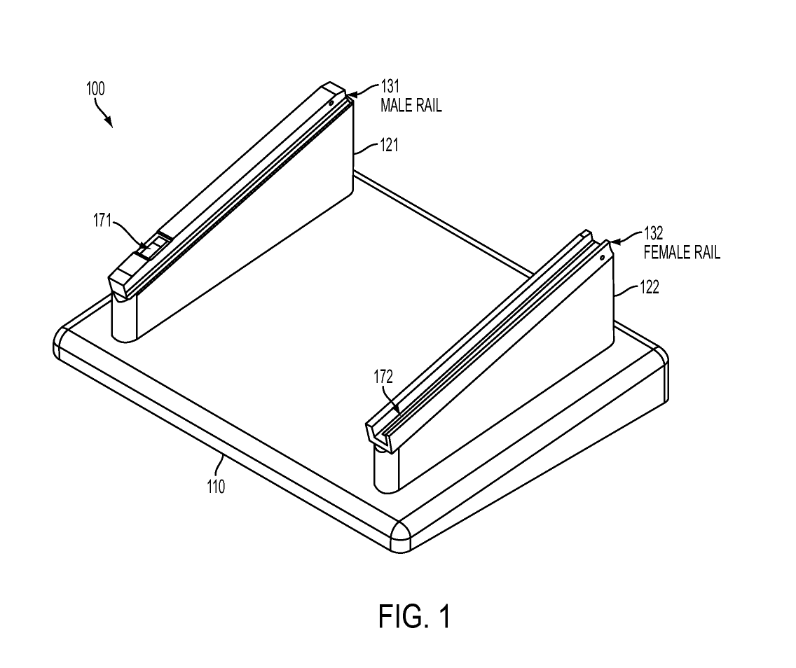

FIG. 1 illustrates a support unit 100 arranged in an example configuration. As shown in FIG. 1, the support unit 100 may include base portion 110, connector supports 121 and 122, and connectors 131 and 132.

Connector supports 121 and 122 may be physically joined to base portion 110 by a variety of conventional means (e.g., screws, glue, hinge, and other fastening means). In some embodiments, the base portion 110 and connector supports 121 and 122 may be formed as a single integral unit. In some other embodiments, the connector supports 121 and 122 may be foldable onto the base portion 110. In addition, the base portion 110 and connector supports 121 and 122 may be formed from a variety of materials. Example materials include a variety of plastics, preferably durable and lightweight plastics. Lightweight metals, such as aluminum, may also be used. Decorative materials, such as wood, may also be used.

The upper surface of connector supports 121 and 122 may be parallel to the upper surface of base portion 110. Alternatively, the upper surface of connector supports 121 and 122 may be angled relative to the upper surface of base portion 110. For example, FIG. 1 depicts an angled configuration of connector supports 121 and 122. Typically, each of the upper surfaces of connector supports 121 and 122 have the same orientation with respect to the upper surface of base portion 110, but different orientations are also feasible.

Connectors 131 and 132 may be physically joined to the connector supports 121 and 122, for example to an upper surface of connector supports 121 and 122, respectively. Alternatively, connectors 131 and 132 may be formed as an integral unit with connector supports 121 and 122 and base portion 110. Using connectors 131 and 132, the support unit 100 may support one or more external devices (not shown). For example, one or more speaker units may be coupled to connectors 131 and 132. In another example, an external amplifier or other audio equipment may be coupled to connectors 131 and 132.

A variety of connectors 131 (e.g., male connectors) and 132 (e.g., female connectors) can be used in order to physically join each connector support 121 and 122 to an adjacent external device. Some example connector types for physically connecting external devices (e.g., modular speaker units, standalone amplifiers, etc.) to the support unit 100 include track, latch, and plug connectors.

In some instances, the connectors 131 and 132 of support unit 100 may also include electrical couplings 171 and 172 that are automatically engaged with an electrical coupling of external device(s) when the connectors are fully engaged. For example, the support unit 100 may be adapted to provide power to an external device.

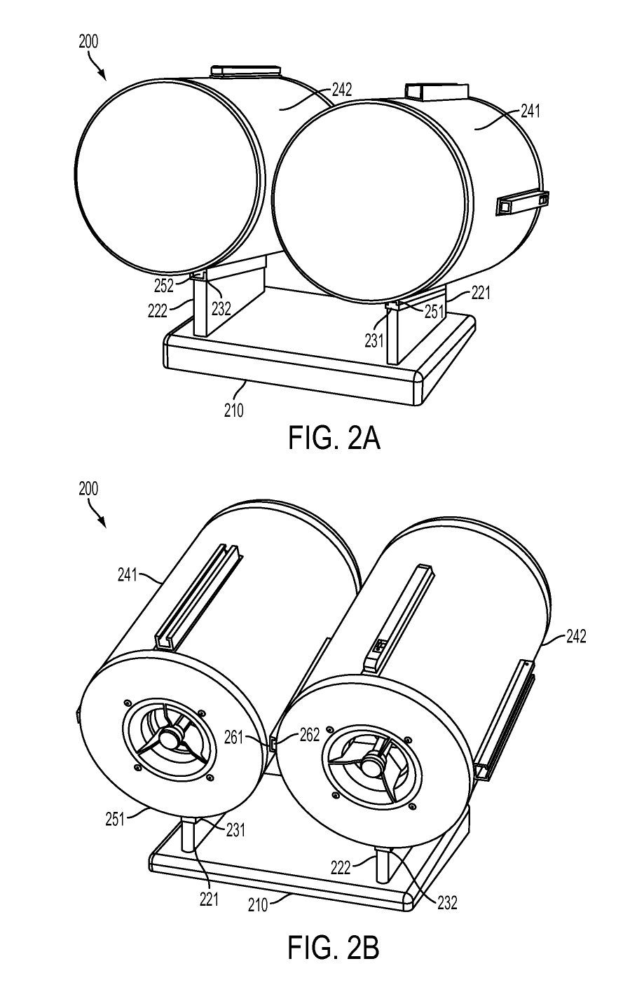

FIG. 2A illustrates a front view of the support unit 200 coupled to modular speakers 241 and 242 in an example configuration. FIG. 2B illustrates a rear view of the support unit 200 coupled to modular speakers units 241 and 242 in an example configuration.

As shown in FIGS. 2A and 2B, the support unit 200 may include base portion 210, connector supports 221 and 222, and connectors 231 and 232. Support unit 200 may support one or more external devices, such as modular speaker units 241 and 242.

A variety of connectors 231 (e.g., male connectors) and 232 (e.g., female connectors) can be used in order to physically join each connector support 221 and 222 to adjacent modular speakers 241 and 242, respectively. The speaker units 241 and 242 may include connectors 251 and 252 that are coupled to connectors 231 and 232, respectively. In addition, connectors 261 and 262 can be used in order to physically join a speaker unit 241 to an adjacent speaker unit 242, enabling the connection of multiple speaker units. Connectors 251, 252 as well as 261, 262 may be the same as connectors 231, 232, respectively, but are provided on the modular speaker units 241 and 242 instead of support unit 200. Some example connector types include track, latch, and plug connectors. In some instances, commercially available connectors may be used, such as Molex model no. 70542-0002 and/or Bourns model no. 70ADH-3-MLO.

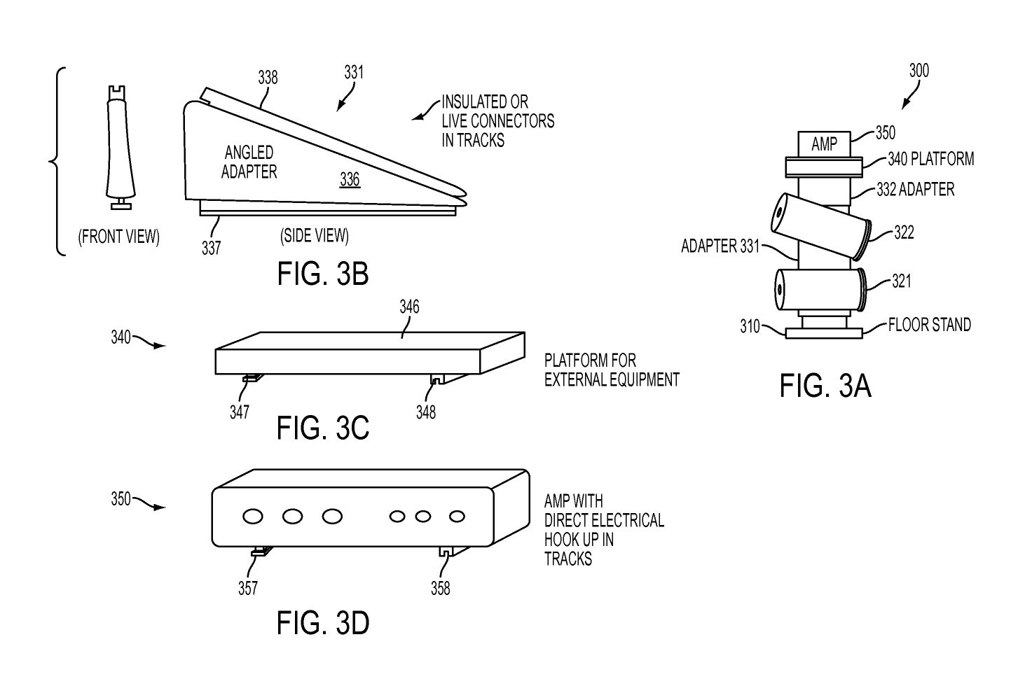

FIGS. 3A-3D illustrate an audio system 300 arranged in an example configuration. As shown in FIG. 3A, the example audio system 300 includes support unit 310, modular speakers units 321 and 322, adapters 331 and 332, platform 340, and amplifier 350.

In the example configuration depicted in FIG. 3A, speakers units 321 are disposed between support unit 310 and adapters 331. Here, adapters 331 and 332 are angled connector supports that may be used to adjust angles between various audio system elements. For example, the use of adapters 331 enables speaker units 322 to be directed at a different angle than speaker units 321. Similarly, the use of adapter 332 enables platform 340 to be directed at a different angle than speaker units 322.

FIG. 3B depicts an example adapter 331. Adapter 331 includes an angled track support 336 and connectors 337 and 338. FIG. 3C depicts an example platform 340. Platform 340 includes a platform section 346 and connectors 347 and 348. Adapters 331, 332 and platform 340 may be formed from a variety of materials. Example materials include a variety of plastics, preferably durable and lightweight plastics. Lightweight metals, such as aluminum, may also be used. Decorative materials, such as wood, may also be used.

FIG. 3D depicts an example external amplifier 350. In some instances, the external amplifier may be disposed on an upper surface of platform 340. Alternatively, the external amplifier may be physically and electrically joined to other audio system elements using optional connectors 357 and 358.

Connectors of the support unit 310, speakers units 321 and 322, adapters 331 and 332, platform 340, and amplifier 350 may also include electrical couplings (not shown) that are automatically engaged with electrical coupling(s) of paired device(s) when the connectors are fully engaged.

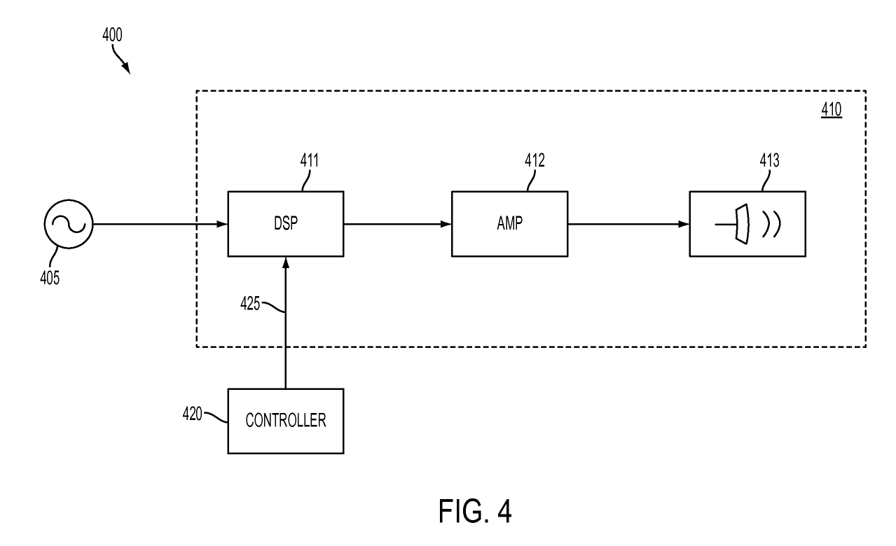

FIG. 4 illustrates a circuit block diagram of a modular speaker unit 410 in an example configuration. Speaker unit 410 may include a digital signal processing (DSP) unit 411, internal amplifier 412, and speaker 413. The speaker unit 410 may be driven by input signal(s) 405 and/or control signal(s) 425 generated at control panel 420.

A fan unit (not shown) or other convention cooling mechanism may be coupled to DSP unit 411 and amplifier 412. The fan unit and/or other convention cooling mechanism are adapted to reduce the operating temperature of the DSP unit 411 and amplifier 412.

Although commercially available amplifiers and DSPs can be coupled to one or more speaker units, the example speaker unit 410 may include an integrated DSP unit 411 and an integrated amplifier 412. The DSP unit 411 and amplifier 412 may be provided individually or as a single integrated circuit. In addition, amplifier 412 may be high powered (e.g., up to 300 watts) and light weight (e.g., under one pound).

In advance of the amplifier 412, DSP unit 411 may adjust various characteristics of the input signal 405. For example, the frequency properties of the input signal may be varied by DSP unit 411. In addition, the functionality of the DSP unit 411 may be programmed by an external control panel 420. For example, instructions to mix another audio signal may be received from the control panel 420 via control signal(s) 425.

DSP unit 411 may be a general purpose processing device, such as a microprocessor, or a special purpose processing device, such as an application specific integrated circuit (ASIC) or field-programmable gate array (FPGA).

Unlike conventional control panels, control panel 420 may be implemented as an audio controller application on portable communication device, such as a laptop, tablet, or mobile phone. In some embodiments, the control signal 425 may be sent wirelessly. By using a software-implemented audio controller application, the need for a costly external control panel can be reduced.

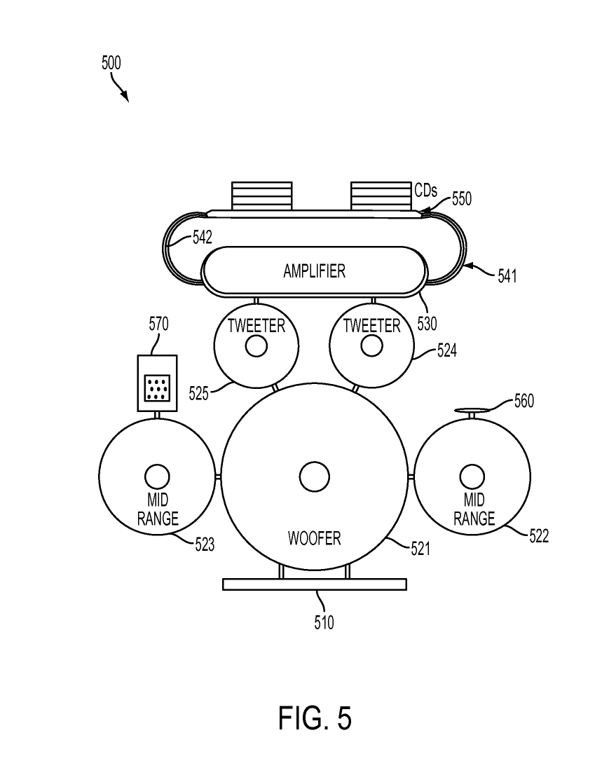

FIG. 5 illustrates an audio system arranged according to another example configuration. The audio system 500 includes multiple audio system elements that are physically and/or electrically joined using the connectors described above. The audio system 500 includes a support unit 510, speaker units 521, 522, 523, 524, and 525, amplifier 530, brackets 541 and 542, shelf 550, compact disk player 560 and portable electronic device 570.

The speaker unit 521 is mounted on supporting unit 510 by connectors described above. In the example configuration depicted in FIG. 5, speaker units of varying sizes and frequency ranges are used. For example, subwoofer 521 (e.g., 12 inch diameter) may be physically and electrically joined to mid-range speakers 522 and 523 (e.g., 8 inch diameter) as well as tweeter speakers 524 and 525 (e.g., 4 inch diameter). External amplifier 530 may be physically and electrically joined to tweeter speakers 524 and 525. Also, the amplifier 530 may be adapted to support shelf 550 via brackets 541 and 542. The brackets 541 and 542, like other components and the shelf 550, have connectors for attaching to adjacent components.

In addition, various electronic devices, such as compact disk player 560 and/or portable electronic device 570 (such as a portable music player or smartphone), may also be coupled to the audio system 500. These electronic devices may be successfully coupled to the audio system 500 provided that the devices include connectors adapted to cooperate with the various components of the system.

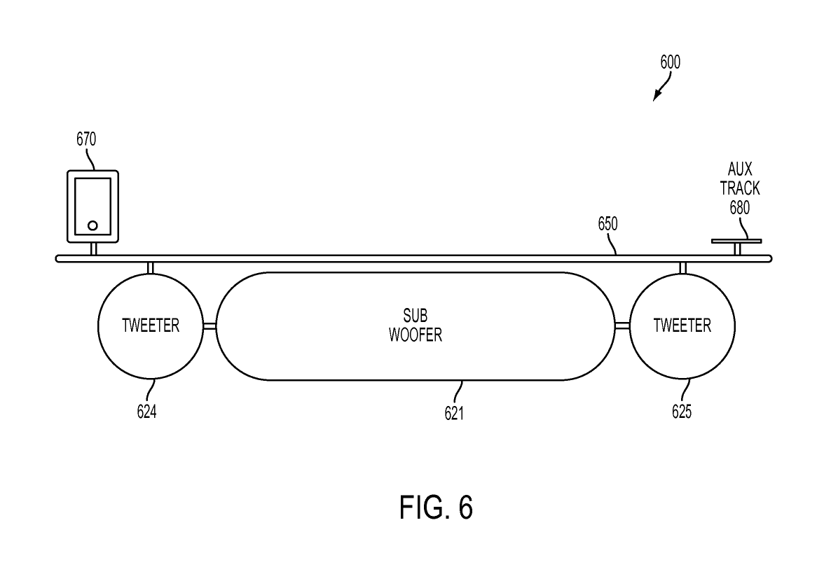

FIG. 6 illustrates an audio system arranged according to another example configuration. The audio system 600 includes multiple audio system elements that are physically and/or electrically joined using the connectors described above. The audio system 600 includes speaker units 621, 624, and 625, shelf 650, portable electronic device 670 and auxiliary connector 680. The speaker unit 621 may be mounted on a support unit (not shown). Alternatively, audio system 600 may be mounted to a wall via shelf 650. The shelf 650 may have connectors for connecting to the various components, such as the speaker units 621, 624, and 625.

In the example configuration depicted in FIG. 6, speaker units of varying sizes and frequency ranges are used. For example, elongated subwoofer 621 (e.g., 12 inch length) may be physically and electrically joined to tweeter speakers 624 and 625 (e.g., 4 inch diameter).

In addition, various electronic devices, such as portable electronic device 670, may also be coupled to the audio system 600. Shelf 650 may include an auxiliary connector 680 adapted to electrically couple an external electronic device. These electronic devices may be successfully coupled to the audio system 600 provided that the devices include connectors adapted to cooperate with the various components of the system.

It will be apparent to those skilled in the art that various modifications and variations can be made in the modular audio system of the present invention without departing from the spirit or scope of the invention. Thus, it is intended that the present invention cover the modifications and variations of this invention provided they come within the scope of the appended claims and their equivalents.

What is claimed is:

1. A support unit comprising:
a base portion;
a plurality of connector supports, each of the plurality of connector supports being coupled to the base portion; and
a plurality of connectors, each of the plurality of connectors being coupled to a respective connector support, the plurality of connectors being adapted to physically join an external device to the support unit.

2. The support unit according to claim 1, wherein each of the plurality of connector supports is foldable onto the base portion.

3. The support unit according to claim 1, wherein each of the plurality of connectors is a track connector.

4. The support unit according to claim 1, wherein each of the plurality of connectors is a latch connector.

5. The support unit according to claim 1, wherein each of the plurality of connectors is a plug connector.

6. The support unit according to claim 1, wherein the external device includes a plurality of modular speaker units.

7. The support unit according to claim 6, wherein the external device further includes a plurality of adapter units, each of the adapter units adapted to adjust an angle between the plurality of modular speaker units and another external device.

8. The support unit according to claim 7, wherein each of the plurality of adapter units includes an electrical coupling adapted to form an electrical connection between the plurality of modular speaker units and the another external device.

9. The support unit according to claim 1, wherein the external device is an amplifier.

10. A modular speaker unit comprising:
a digital signal processing unit that is disposed within the modular speaker unit and adapted to receive an input signal and a control signal; and
an amplifier that is disposed within the modular speaker unit and adapted to drive a speaker diaphragm.

11. The speaker unit according to claim 10, further comprising a fan that is adapted to reduce the operating temperature of the digital signal processing unit and the amplifier.

12. The speaker unit according to claim 10, wherein the digital signal processing unit and the amplifier are provided as a single integrated circuit.

13. The speaker unit according to claim 10, wherein the amplifier provides a power output of up to 300 watts.

14. The speaker unit according to claim 10, wherein the amplifier has a weight of less than one pound.

15. The speaker unit according to claim 10, wherein the functionality of the digital signal processing unit is programmed by an external control panel.

16. The speaker unit according to claim 15, wherein the control panel is implemented as an audio controller application on a portable communication device.

17. The speaker unit according to claim 16, wherein the digital signal processing unit is implemented by an application specific integrated circuit.

18. The speaker unit according to claim 16, wherein the digital signal processing unit is implemented by a field-programmable gate array.
